(19) United States
(12) Patent Application Publication
(10) Pub. No.: US 2025/0202221 A1
(43) Pub. Date: Jun. 19, 2025

(54) SWITCHING ELEMENT CONTROL APPARATUS

(71) Applicant: Mitsubishi Electric Corporation, Tokyo (JP)

(72) Inventors: Yasuhiro WATANABE, Tokyo (JP); Shohei SANO, Fukuoka (JP)

(73) Assignee: Mitsubishi Electric Corporation, Tokyo (JP)

(21) Appl. No.: 18/917,977

(22) Filed: Oct. 16, 2024

(30) Foreign Application Priority Data
Dec. 18, 2023 (JP) 2023-212835

(51) Int. Cl. H02H 3/08; H02H 1/00

(52) U.S. Cl. CPC H02H 3/08; H02H 1/0007

(57) ABSTRACT

A switching element control apparatus includes: a drive circuit that drives a switching element according to a drive control signal; a first reference power supply that outputs a first reference voltage; a reference voltage control unit that controls the first reference power supply according to a reference voltage setting signal to adjust the first reference voltage; and an overcurrent detection circuit that outputs a first cutoff signal when an on-voltage of the switching element is equal to or higher than the first reference voltage. The drive circuit performs a hard cutoff of the switching element according to the first cutoff signal.

### BACKGROUND OF THE INVENTION

### Field of the Invention

The present disclosure relates to a switching element control apparatus, and particularly relates to an overcurrent protection function of a switching element.

### Description of the Background Art

Switching element control apparatuses having an overcurrent protection function for protecting a switching element from an overcurrent have been known. For example, Japanese Patent Application Laid-Open No. 2001-8492 below discloses a switching element control apparatus that determines whether or not a switching element is in an unsaturated state from an on-voltage of the switching element, determines that the switching element in the unsaturated state is in an overcurrent state (for example, short-circuited), and cuts off the switching element. The overcurrent protection function in Japanese Patent Application Laid-Open No. 2001-8492 protects the switching element from a high current caused by a short circuit of a load or the like, and performs a “soft cutoff” for turning off the switching element slower than normal operation in order to suppress generation of an excessive surge voltage due to di/dt and parasitic inductance L at the time of cutting off the high current. On the other hand, turning off the switching element at a high speed (for example, at a speed equivalent to the normal operation) is referred to as a “hard cutoff”.

In the soft cutoff of the switching element, the time for which an overcurrent flows is longer than that in the hard cutoff, so that thermal stress due to the current increases. Therefore, the soft cutoff of the switching element has a problem that the reliability of the switching element deteriorates.

Characteristics of the switching elements include a difference in specification for each product and a variation for each individual. Therefore, in a method of detecting the overcurrent (unsaturated state) from the on-voltage of the switching element, in order to prevent erroneous detection of the unsaturated state, a threshold is set to about three times or more a rated value (about 10 V) in order to determine whether or not the switching element is in the unsaturated state. This means that, even if an overcurrent equal to or higher than a rated value flows through the switching element, the overcurrent is not detected unless the value thereof reaches three times the rated value, so that the overcurrent detection accuracy is low. As a result, the overcurrent protection function does not work for an overcurrent not reaching three times the rated value, and stress is applied to the switching element, which may lead to breakdown of the switching element in some cases. Such an overcurrent may occur due to a factor other than a short circuit, for example, when a load temporarily increases.

### SUMMARY

An object of the present disclosure is to improve the reliability of a switching element and the overcurrent detection accuracy in a switching element control apparatus having an overcurrent protection function.

A switching element control apparatus according to the present disclosure includes a drive circuit, a first reference power supply, a reference voltage control unit, and an overcurrent detection circuit. The drive circuit drives a switching element according to a drive control signal. The first reference power supply outputs a first reference voltage. The reference voltage control unit adjusts the first reference voltage by controlling the first reference power supply according to a reference voltage setting signal. The overcurrent detection circuit outputs a first cutoff signal when an on-voltage of the switching element is equal to or higher than the first reference voltage. The drive circuit performs a hard cutoff of the switching element according to the first cutoff signal.

According to the switching element control apparatus of the present disclosure, it is possible to improve the reliability of the switching element and the overcurrent detection accuracy.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a diagram illustrating a configuration of a switching element control apparatus according to a first preferred embodiment; and

FIG. 2 is a diagram illustrating a configuration of a switching element control apparatus according to a second preferred embodiment.

### DESCRIPTION OF THE PREFERRED EMBODIMENTS

### First Preferred Embodiment

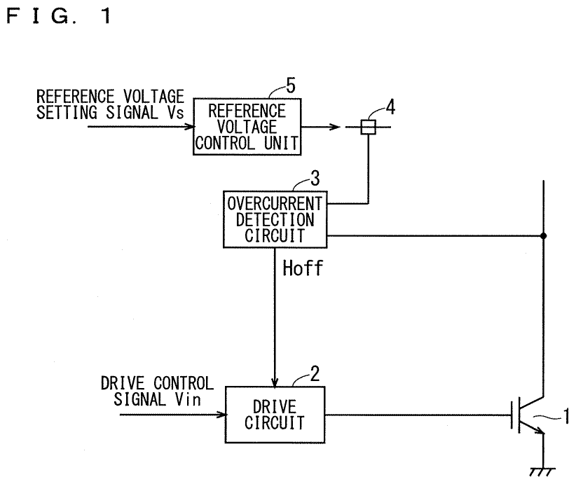

FIG. 1 is a diagram illustrating a configuration of a switching element control apparatus according to a first preferred embodiment. As illustrated in FIG. 1, the switching element control apparatus controls the operation of a switching element 1, and includes a drive circuit 2, an overcurrent detection circuit 3, a first reference power supply 4, and a reference voltage control unit 5.

In the present preferred embodiment, the switching element 1 is an insulated gate bipolar transistor (IGBT). However, a type of the switching element 1 is not limited, and may be, for example, a metal oxide semiconductor field effect transistor (MOSFET), a bipolar transistor, or the like. A main material of the switching element 1 is most generally silicon (Si), but may be, for example, a wide bandgap semiconductor such as silicon carbide (SiC) or gallium nitride (GaN). In a case where the material of the switching element 1 is the wide bandgap semiconductor, characteristics excellent in operation at a high voltage, a high current, and a high temperature are obtained as compared with the case of silicon.

The drive circuit 2 drives the switching element 1 according to a drive control signal Vin. Specifically, the drive circuit 2 outputs a gate signal corresponding to the drive control signal Vin to a gate of the switching element 1 to switch between on and off of the switching element 1.

The first reference power supply 4 outputs a first reference voltage. The first reference voltage output from the first reference power supply 4 is variable, and a value of the first reference voltage can be controlled by the reference voltage control unit 5. The reference voltage control unit 5 adjusts the first reference voltage output from the first reference power supply 4 according to a reference voltage setting signal Vs.

The overcurrent detection circuit 3 is connected to a collector of the switching element 1 and the first reference power supply 4, and a collector voltage of the switching element 1 and the first reference voltage are input to the overcurrent detection circuit 3. When an on-voltage of the switching element 1 (that is, the collector voltage when switching element 1 is in an on-voltage) is equal to or higher than the first reference voltage, the overcurrent detection circuit 3 determines that an overcurrent has occurred in the switching element 1, and outputs a hard cutoff signal Hoff which is a first cutoff signal for cutting off the switching element 1. The hard cutoff signal Hoff output from the overcurrent detection circuit 3 is input to the drive circuit 2.

When the hard cutoff signal Hoff is input, the drive circuit 2 protects the switching element 1 from the overcurrent by outputting the gate signal for turning off the switching element 1 to bring the switching element 1 into an off-state (cutoff state) regardless of the drive control signal Vin.

The operation in which the drive circuit 2 turns off the switching element 1 according to the hard cutoff signal Hoff is a hard cutoff. A turn-off speed in the hard cutoff is, for example, the same speed as a turn-off speed in normal operation. In a case where the drive circuit 2 performs the hard cutoff of the switching element 1 when the overcurrent flows through the switching element 1, the switching element 1 is quickly protected from the overcurrent as compared with the case of a soft cutoff, and thus stress of the switching element 1 can be mitigated, and the reliability of the switching element 1 is improved.

As can be seen from the above description, the first reference voltage output from the first reference power supply 4 is a threshold of the on-voltage of the switching element 1 for determining whether or not an overcurrent has flowed through the switching element 1. The first reference voltage can be adjusted using the reference voltage setting signal Vs input to the reference voltage control unit 5. Thus, even if there is a difference in specification for each product or a variation for each individual in the characteristics of the switching elements 1, the first reference voltage as the threshold can be set to a value suitable for an on-voltage of the switching element 1 that is actually used by adjusting the reference voltage setting signal Vs in accordance with an actual product specification or variation of this switching element 1. Thus, it is possible to improve the overcurrent detection accuracy by setting the first reference voltage to a region (for example, a range from 0 V to 10 V) lower than three times a rated value.

Since the first reference voltage is set to the region lower than three times the rated value, the overcurrent detection circuit 3 can detect the occurrence of the overcurrent at an early stage, and thus there is a possibility that an excessive surge voltage is suppressed even if the hard cutoff of the switching element 1 is performed. This also contributes to the improvement in the reliability of the switching element 1. Note that it is sufficient to adjust a value of the first reference voltage appropriately according to a request such as an actual use condition of the switching element 1 or an intention of safety design, for example.

In the switching element control apparatus of FIG. 1, the overcurrent detection circuit 3 is directly connected to the collector of the switching element 1. Such connection can be made by configuring the overcurrent detection circuit 3 using a MOS transistor having a withstand voltage equal to or higher than that of the switching element 1. Alternatively, the overcurrent detection circuit 3 may be configured using a high-voltage diode and a limiting resistor, but in this case, it should be noted that the first reference voltage serving as the threshold cannot be set to be equal to or lower than a forward voltage (VF) of the diode, and variations in characteristics of the high-voltage diode and the limiting resistor also need to be considered.

As a method in which the overcurrent detection circuit 3 detects an overcurrent lower than three times the rated value of the switching element 1, there is also a method in which a shunt resistor is inserted into a current path of the switching element 1, and the overcurrent detection circuit 3 detects the overcurrent from a voltage generated in the shunt resistor. However, this method has a disadvantage that power loss occurs in the shunt resistor even during normal operation.

As means for suppressing the power loss in this shunt resistor method, there is also a method in which a current sense terminal into which a part of a current flowing through the switching element 1 flows is provided in the switching element 1, and the overcurrent detection circuit 3 detects an overcurrent from the current flowing through the current sense terminal. However, it should be noted that in order to adopt this method, it is necessary to increase a chip area of the switching element 1 by providing a structure for current sensing, increase the number of assembly steps, increase a wiring pattern on a substrate on which the switching element 1 is mounted, and the like, so that cost increases. The cost increase due to the increase in the chip area is more remarkable in a case where silicon carbide (SiC) or the like that requires high material cost is used as the material of the switching element 1.

Conversely, the configuration in which the overcurrent detection circuit 3 is directly connected to the collector of the switching element 1 as illustrated in FIG. 1 is advantageous in terms of loss and cost.

### Second Preferred Embodiment

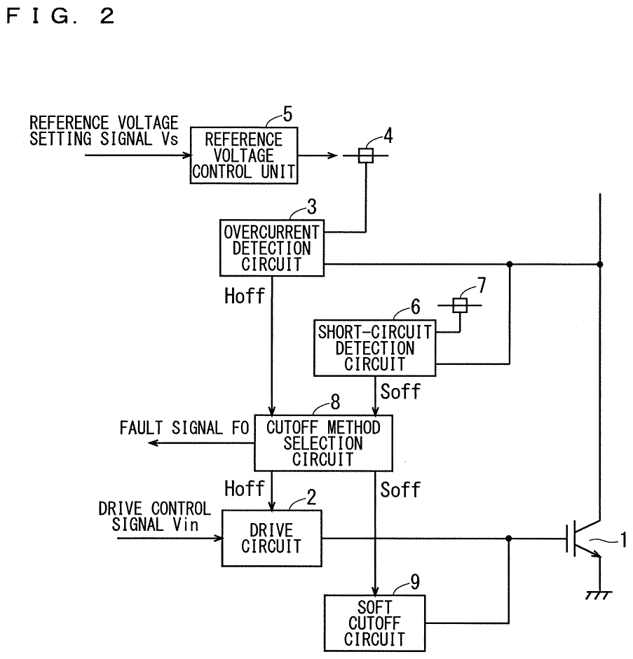

FIG. 2 is a diagram illustrating a configuration of a switching element control apparatus according to a second preferred embodiment. The configuration of the switching element control apparatus according to the second preferred embodiment is obtained by adding a short-circuit detection circuit 6, a second reference power supply 7, a cutoff method selection circuit 8, and a soft cutoff circuit 9 to the configuration of the first preferred embodiment (FIG. 1). Note that configurations and operations of the switching element 1, the drive circuit 2, the overcurrent detection circuit 3, the first reference power supply 4, and the reference voltage control unit 5 illustrated in FIG. 2 may be basically similar to those of the first preferred embodiment, and thus differences from the first preferred embodiment will be described herein, and description overlapping with that of the first preferred embodiment will be omitted.

The second reference power supply 7 outputs a second reference voltage. The second reference voltage is fixed to an on-voltage (that is, 10 V or higher) at which the switching element 1 can be regarded to be in an unsaturated state in consideration of variations in characteristics of the switching elements 1. Meanwhile, similarly to the first reference power supply 4, the second reference power supply 7 may also be configured to be capable of adjusting the second reference voltage according to a signal input from the outside.

The short-circuit detection circuit 6 is connected to a collector of the switching element 1 and the second reference power supply 7, and a collector voltage of the switching element 1 and the second reference voltage are input to the short-circuit detection circuit 6. When the on-voltage of the switching element 1 is equal to or higher than the second reference voltage, the short-circuit detection circuit 6 determines that a load of the switching element 1 is in a short-circuit state, and outputs a soft cutoff signal Soff that is a second cutoff signal for cutting off the switching element 1. In this manner, the second reference voltage output from the second reference power supply 7 is a threshold of the on-voltage of the switching element 1 for determining whether or not the load of the switching element 1 is in the short-circuit state.

On the other hand, the first reference voltage output from the first reference power supply 4 is a threshold for determining whether or not an overcurrent has flowed through the switching element 1 as in the first preferred embodiment. Therefore, the reference voltage control unit 5 sets the first reference voltage to be lower than three times a rated value. That is, the first reference voltage is set to a value lower than the second reference voltage.

The soft cutoff circuit 9 performs a soft cutoff of the switching element 1 according to the soft cutoff signal Soff output from the short-circuit detection circuit 6. However, as described below, the soft cutoff signal Soff is not directly input from the short-circuit detection circuit 6 to the soft cutoff circuit 9, but is input to the soft cutoff circuit 9 via the cutoff method selection circuit 8.

The hard cutoff signal Hoff output from the overcurrent detection circuit 3 and the soft cutoff signal Soff output from the short-circuit detection circuit 6 are input to the cutoff method selection circuit 8. When only the hard cutoff signal Hoff is input, the cutoff method selection circuit 8 inputs the hard cutoff signal Hoff to the drive circuit 2 to perform a hard cutoff of the switching element 1. In addition, when only the soft cutoff signal Soff or both the hard cutoff signal Hoff and the soft cutoff signal Soff are input, the cutoff method selection circuit 8 inputs the soft cutoff signal Soff to the soft cutoff circuit 9 to perform the soft cutoff of the switching element 1.

When the soft cutoff signal Soff is input from the cutoff method selection circuit 8, the soft cutoff circuit 9 performs the soft cutoff of the switching element 1. When the hard cutoff signal Hoff is input from the cutoff method selection circuit 8, the drive circuit 2 performs the hard cutoff of the switching element 1. Since the overcurrent detection circuit 3 outputs the soft cutoff signal Soff when both the hard cutoff signal Hoff and the soft cutoff signal Soff are input, the soft cutoff of the switching element 1 is preferentially performed when the overcurrent detection circuit 3 detects an overcurrent and the short-circuit detection circuit 6 detects a short circuit at the same time.

According to the switching element control apparatus of the second preferred embodiment, when an overcurrent lower than three times a rated value flows through the switching element 1, the drive circuit 2 performs the hard cutoff of the switching element 1, so that an increase in thermal stress and an increase in loss due to the overcurrent are suppressed. In addition, when a current (overcurrent due to the short circuit of the load) equal to or higher than three times the rated value flows through the switching element 1, the soft cutoff circuit 9 performs the soft cutoff of the switching element 1, and the occurrence of an excessive surge voltage is suppressed. Since an appropriate cutoff method according to the magnitude of the overcurrent flowing through the switching element 1 is performed in this manner, the reliability of the switching element 1 can be further improved as compared with the first preferred embodiment.

Each of the switching element control apparatuses of the first and second preferred embodiments may output a fault signal FO that reports an abnormality to a system in which the switching element control apparatus is incorporated when the switching element 1 is cut off in order to protect the switching element 1 from the overcurrent. For example, in the second preferred embodiment, the fault signal FO may be output from the cutoff method selection circuit 8 as illustrated in FIG. 2, and the cutoff method selection circuit 8 may be configured not to output the fault signal FO when the hard cutoff signal Hoff is input from the overcurrent detection circuit 3 (that is, when the overcurrent lower than three times the rated value is detected, hereinafter referred to as “the time of detecting the overcurrent”), and to output the fault signal FO only when the soft cutoff signal Soff is input from the second reference power supply 7 (that is, when the short-circuit state of the load is detected, hereinafter referred to as “the time of detecting the short circuit”). In this case, the system interrupts normal operation at the time of detecting the short circuit, but recognizes the time of detecting the overcurrent as a normal state and continues the normal operation.

In general, as the switching element 1, one having a rated value higher than a current during steady-state operation (one having so-called over-performance) is selected in order to have a margin for the maximum current in use in consideration of the worst case. As described above, when the system continues the normal operation at the time of detecting the overcurrent, the current flowing through the switching element 1 is automatically suppressed to a set value. Therefore, as the switching element 1, one having a rated value close to the current during the steady-state operation can be used, which leads to cost reduction.

In addition, when the switching element 1 is an IGBT, steady-state loss in a low current region is large because the IGBT has a built-in voltage. Therefore, depending on characteristics of the IGBT, it can also be expected that loss is reduced by continuing steady-state operation even when an overcurrent near a rated value of the IGBT occurs.

Note that each of the preferred embodiments can be freely combined, and each of the preferred embodiments can be appropriately modified or omitted.

### APPENDICES

Hereinafter, various aspects of the present disclosure will be collectively described as appendices.

### Appendix 1

A switching element control apparatus comprising:
a drive circuit that drives a switching element according to a drive control signal;
a first reference power supply that outputs a first reference voltage;
a reference voltage control unit that controls the first reference power supply according to a reference voltage setting signal to adjust the first reference voltage; and
an overcurrent detection circuit that outputs a first cutoff signal when an on-voltage of the switching element is equal to or higher than the first reference voltage,
wherein the drive circuit performs a hard cutoff of the switching element according to the first cutoff signal.

### Appendix 2

The switching element control apparatus according to Appendix 1, wherein the switching element is made of silicon carbide.

### Appendix 3

The switching element control apparatus according to Appendix 1 or 2, further comprising:
a second reference power supply that outputs a second reference voltage;
a short-circuit detection circuit that outputs a second cutoff signal when the on-voltage of the switching element is equal to or higher than the second reference voltage;
a soft cutoff circuit that performs a soft cutoff of the switching element according to the second cutoff signal; and
a cutoff method selection circuit that receives the first cutoff signal and the second cutoff signal, inputs the first cutoff signal to the drive circuit to perform the hard cutoff of the switching element when only the first cutoff signal is input, and inputs the second cutoff signal to the soft cutoff circuit to perform the soft cutoff of the switching element when only the second cutoff signal or both the first cutoff signal and the second cutoff signal are input.

### Appendix 4

The switching element control apparatus according to Appendix 3, wherein the first reference voltage is set to a value lower than the second reference voltage.

### Appendix 5

The switching element control apparatus according to Appendix 3 or 4, wherein a fault signal is output when the second cutoff signal is output from the short-circuit detection circuit.

While the disclosure has been shown and described in detail, the foregoing description is in all aspects illustrative and not restrictive. It is therefore understood that numerous modifications and variations can be devised.

What is claimed is:

1. A switching element control apparatus comprising:
a drive circuit that drives a switching element according to a drive control signal;
a first reference power supply that outputs a first reference voltage;
a reference voltage control unit that controls the first reference power supply according to a reference voltage setting signal to adjust the first reference voltage; and
an overcurrent detection circuit that outputs a first cutoff signal when an on-voltage of the switching element is equal to or higher than the first reference voltage,
wherein the drive circuit performs a hard cutoff of the switching element according to the first cutoff signal.

2. The switching element control apparatus according to claim 1, wherein the switching element is made of silicon carbide.

3. The switching element control apparatus according to claim 1, further comprising:
a second reference power supply that outputs a second reference voltage;
a short-circuit detection circuit that outputs a second cutoff signal when the on-voltage of the switching element is equal to or higher than the second reference voltage;
a soft cutoff circuit that performs a soft cutoff of the switching element according to the second cutoff signal; and
a cutoff method selection circuit that receives the first cutoff signal and the second cutoff signal, inputs the first cutoff signal to the drive circuit to perform the hard cutoff of the switching element when only the first cutoff signal is input, and inputs the second cutoff signal to the soft cutoff circuit to perform the soft cutoff of the switching element when only the second cutoff signal or both the first cutoff signal and the second cutoff signal are input.

4. The switching element control apparatus according to claim 2, further comprising:
a second reference power supply that outputs a second reference voltage;
a short-circuit detection circuit that outputs a second cutoff signal when the on-voltage of the switching element is equal to or higher than the second reference voltage;
a soft cutoff circuit that performs a soft cutoff of the switching element according to the second cutoff signal; and
a cutoff method selection circuit that receives the first cutoff signal and the second cutoff signal, inputs the first cutoff signal to the drive circuit to perform the hard cutoff of the switching element when only the first cutoff signal is input, and inputs the second cutoff signal to the soft cutoff circuit to perform the soft cutoff of the switching element when only the second cutoff signal or both the first cutoff signal and the second cutoff signal are input.

5. The switching element control apparatus according to claim 3, wherein the first reference voltage is set to a value lower than the second reference voltage.

6. The switching element control apparatus according to claim 4, wherein the first reference voltage is set to a value lower than the second reference voltage.

7. The switching element control apparatus according to claim 3, wherein a fault signal is output when the second cutoff signal is output from the short-circuit detection circuit.

8. The switching element control apparatus according to claim 4, wherein a fault signal is output when the second cutoff signal is output from the short-circuit detection circuit.

9. The switching element control apparatus according to claim 5, wherein a fault signal is output when the second cutoff signal is output from the short-circuit detection circuit.

10. The switching element control apparatus according to claim 6, wherein a fault signal is output when the second cutoff signal is output from the short-circuit detection circuit.
